(19) United States
(12) Patent Application Publication
(10) Pub. No.: US 2026/0255838 A1
(43) Pub. Date: Aug. 27, 2026

(54) DISPLAY DEVICE

(71) Applicant: Sharp Display Technology Corporation, Kameyama City, Mie (JP)

(72) Inventors: Shigetsugu YAMANAKA, Kameyama City, Mie (JP); Kohzoh NAKAMURA, Kameyama City, Mie (JP); Shuji NISHIOKA, KameyamaCity, Mie (JP)

(21) Appl. No.: 19/161,671

(22) PCT Filed: Mar. 6, 2023
(86) PCT No.: PCT/JP2023/008267

§ 371 Date: Sep. 2, 2025

(51) Int. Cl. H10K 59/65; H10K 59/35

(52) U.S. Cl. CPC H10K 59/65; H10K 59/353

(57) ABSTRACT

A display device includes a display portion including a non-camera region and a camera region where imaging light is introduced. The non-camera region includes a plurality of first light-emitting elements each including an electrode and emitting a first color. The camera region includes a plurality of second light-emitting elements each including an electrode and emitting a first color. The plurality of first light-emitting elements are formed so that the electrode center of each of the plurality of first light-emitting elements coincides with an intersection point of a virtual regular grid pattern of the display portion. The plurality of second light-emitting elements are formed so that the electrode center of each of the plurality of second light-emitting elements is displaced from the intersection point.

### TECHNICAL FIELD

The disclosure relates to a display device formed with a camera region where imaging light is introduced from a side of a display surface in a display portion.

### BACKGROUND ART

In recent years, a technique is known in which a camera unit is installed on a back surface side of a display portion in a display device, and a camera region where imaging light is introduced from a side of a display surface of the display device to a camera unit is formed in a display portion. Cited Reference 1 discloses an image display device for improving the characteristics of light transmitted through a display panel.

### CITATION LIST

### Patent Literature

PTL 1: WO 2021/256194

### SUMMARY OF INVENTION

### Technical Problem

If the camera region is formed in the display portion, a light-emitting element is formed in the camera region so that the camera region functions as a part of the display portion. In such a case, diffraction occurs in imaging light transmitting between electrodes of the light-emitting element, and the quality of imaging by the camera unit may be reduced.

### Solution to Problem

A light-emitting device according to an embodiment of the disclosure includes a display portion including a camera region where imaging light is introduced and a non-camera region, in which the non-camera region includes a plurality of first light-emitting elements each including an electrode and emitting a first color, the camera region includes a plurality of second light-emitting elements each including an electrode and emitting the first color, the plurality of first light-emitting elements are formed such that an electrode center of each of the plurality of first light-emitting elements coincides with an intersection point of a virtual regular grid pattern of the display portion, and the plurality of second light-emitting elements are formed such that an electrode center of each of the plurality of second light-emitting elements is displaced from the intersection point.

### Advantageous Effects of Invention

An object of the present disclosure is to reduce interference between diffraction light beams of imaging light transmitting through a camera region and to reduce deterioration in quality of imaging in the camera region.

### BRIEF DESCRIPTION OF DRAWINGS

FIG. 1 is a schematic enlarged view of a boundary between a first display region and a third display region and a vicinity thereof and a boundary between the third display region and a second display region and a vicinity thereof according to a first embodiment.

FIG. 2 is a schematic plan view of a display device according to the first embodiment.

FIG. 3 is an enlarged schematic view of the first display region and the third display region and a vicinity thereof in a display portion of the display device according to the first embodiment.

FIG. 4 is a schematic cross-sectional side view of the first display region and the third display region of the display device according to the first embodiment.

FIG. 5 is a schematic enlarged view of a boundary between a first display region and a third display region and a vicinity thereof and a boundary between the third display region and a second display region and a vicinity thereof according to a second embodiment.

FIG. 6 is a schematic enlarged view of a boundary between a first display region and a third display region and a vicinity thereof and a boundary between the third display region and a second display region and a vicinity thereof according to a third embodiment.

FIG. 7 is a schematic enlarged view of a boundary between a first display region and a third display region and a vicinity thereof and a boundary between the third display region and a second display region and a vicinity thereof according to a fourth embodiment.

FIG. 8 is a schematic enlarged view of a boundary between a first display region and a third display region and a vicinity thereof and a boundary between the third display region and a second display region and a vicinity thereof according to a fifth embodiment.

### DESCRIPTION OF EMBODIMENTS

### First Embodiment

### Overview of Display Device

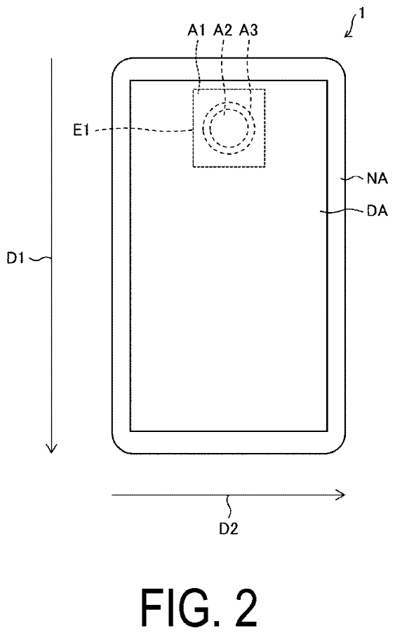

FIG. 2 is a schematic plan view of a display device 1. The display device 1 includes a display portion DA and a frame portion NA formed around the display portion DA. The display device 1 performs display in the display portion DA by controlling light emission from each of a plurality of light-emitting elements, which will be described below, formed in the display portion DA. In the frame portion NA, a driver or the like for driving each of the plurality of light-emitting elements of the display portion DA may be formed.

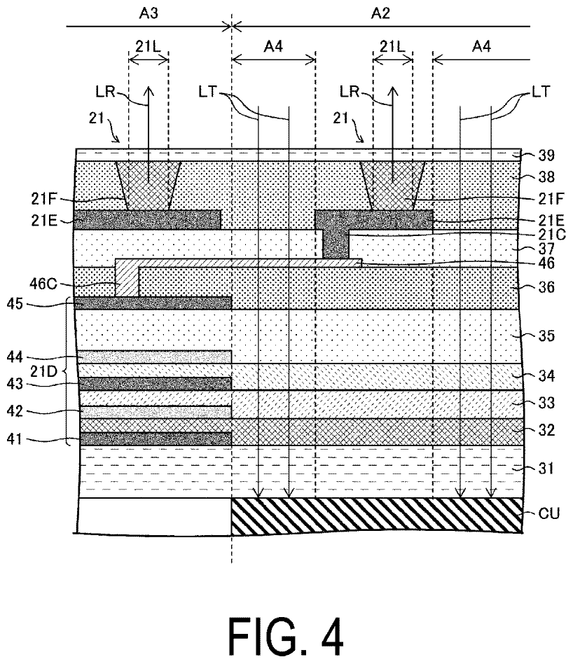

Note that in the present embodiment, a plan view of the display device 1 refers to viewing the display device 1 from a direction perpendicular to an upper face being a light-emitting face of the display portion DA of the display device 1. Herein, in the present specification, as illustrated in FIG. 2, in the plan view of the display device 1, a direction from an upper side to a lower side of the display device 1 is defined as a first direction D1, and a direction from a left side to a right side of the display device 1 is defined as a second direction D2. Hereinafter, in the drawings of the present specification except FIG. 4, the first direction D1 is a direction from the upper side to the lower side on the paper surface, and the second direction D2 is a direction from the left side to the right side on the paper surface.

The display device 1 according to the present embodiment includes, for example, a light-emitting element formed for each subpixel of the display portion DA. The light-emitting element includes, for example, a pixel electrode formed for each subpixel, a common electrode formed in common to a plurality of the subpixels, and a function layer including a light-emitting layer formed between the pixel electrode and the common electrode. The display portion DA drives each pixel electrode, based on a signal input from the driver of the frame portion NA to control light emission of each light-emitting element to display an object.

Hereinafter, unless otherwise specified, each pixel electrode in the display portion DA is a light-reflecting electrode which reflects visible light, and the common electrode is a transmitting electrode which transmits visible light. Each pixel electrode of the display portion DA is an anode of a light-emitting element, and the common electrode is a cathode of a light-emitting element. Note that each pixel circuit which drives each pixel electrode in the display portion DA may be formed of a member reflecting visible light.

In the present embodiment, the display portion DA includes a first display region A1 serving as a non-camera region, a second display region A2 serving as a camera region, and a third display region A3 serving as a non-camera region. For example, the second display region A2 and the third display region A3 are formed on the inner side in the display portion DA from the first display region A1. The second display region A2 is formed on the inner side in the display portion DA from the third display region A3. For example, the second display region A2 has a substantially circular shape in the plan view of the display device 1. In such a case, the third display region A3 is located between the first display region A1 and the second display region A2, and has a ring shape with substantially the same widths in the plan view of the display device 1, for example.

### First Display Region

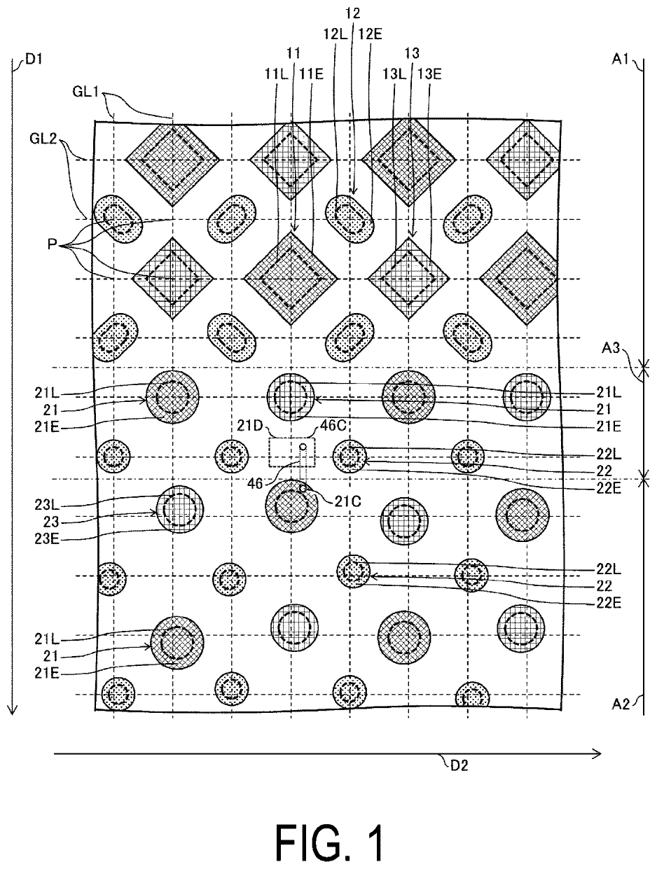

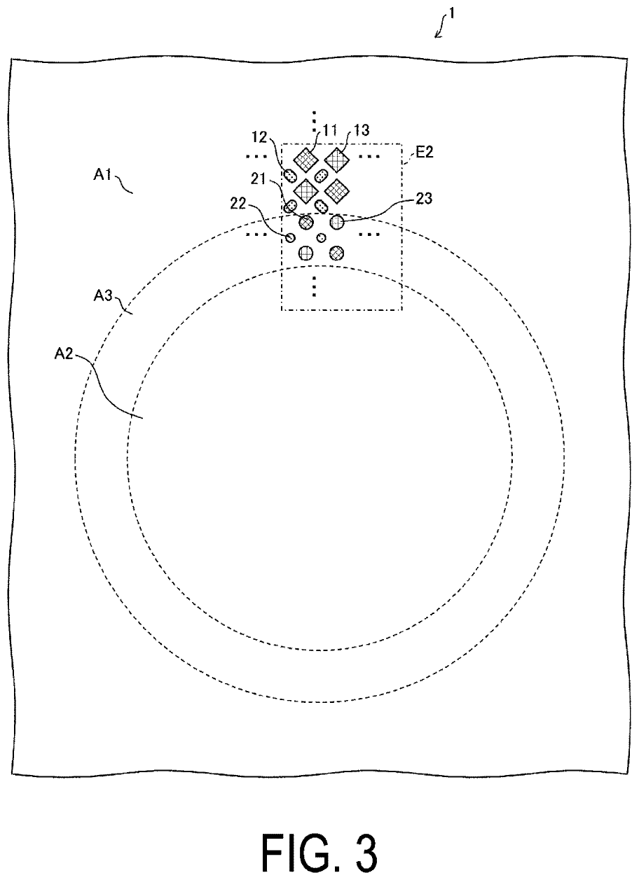

The first display region A1, the second display region A2, and the third display region A3 will be described in more detail with reference to FIGS. 1 and 3. FIG. 3 is a schematic enlarged view of a region E1 illustrated in FIG. 2, in other words, an enlarged view of the second display region A2, the third display region A3, and the first display region A1 in the vicinity of the second display region A2 in the display portion DA. FIG. 1 is a schematic enlarged view of a region E2 illustrated in FIG. 3, in other words, a further enlarged view of a boundary between the first display region A1 and the third display region A3 and a vicinity thereof and a boundary between the second display region A2 and the third display region A3 and a vicinity thereof.

Note that in FIG. 3, only a pixel electrode described below is extracted from the light-emitting elements for illustration. In other words, in FIG. 3, each pixel electrode is illustrated through the function layer formed for each pixel electrode and the common electrode formed in common to a plurality of the pixel electrodes. In FIG. 1, only each pixel electrode, one of transparent wiring lines 46 electrically connected to an electrode 21E described below, and one of pixel circuits 21D that drive the electrode 21E are extracted and illustrated.

As illustrated in FIG. 3, the first display region A1 includes, for example, a plurality of light-emitting elements 11, a plurality of light-emitting elements 12, and a plurality of light-emitting elements 13 serving as first light-emitting elements. The light-emitting elements 11, the light-emitting elements 12, and the light-emitting elements 13 are two-dimensionally arranged on the first display region A1.

Each of the light-emitting elements 11, the light-emitting elements 12, and the light-emitting elements 13 includes an electrode 11E, an electrode 12E, and an electrode 13E serving as an electrode, respectively, and the electrode 11E, the electrode 12E, and the electrode 13E include a plurality of the electrodes 11E, a plurality of the electrodes 12E, and a plurality of the electrodes 13E. Each of the electrode 11E, the electrode 12E, and the electrode 13E is a pixel electrode formed for each subpixel of the display portion DA. As described below, the display device 1 includes a function layer of each light-emitting element formed at a position overlapping each of the electrode 11E, the electrode 12E, and the electrode 13E, and a common electrode common to each pixel electrode in the plan view of the display device 1. Therefore, as illustrated in FIG. 1, in the first display region A1, a light-emitting region 11L, a light-emitting region 12L, and a light-emitting region 13L are formed at positions overlapping the electrode 11E, the electrode 12E, and the electrode 13E, respectively, in the plan view of the display device 1.

Now, in the present embodiment, as illustrated in FIG. 1, a virtual regular grid pattern including a plurality of first grid lines GL1 along the first direction D1 and a plurality of second grid lines GL2 along the second direction D2 is formed in the display portion DA of the display device 1. Each of the plurality of first grid lines GL1 is formed at a substantially regular interval in the second direction D2, and each of the plurality of second grid lines GL2 is formed at a substantially regular interval in the first direction D1. In the present embodiment, as illustrated in FIG. 1, in the display portion DA of the display device 1, an intersection point P of the regular grid pattern is virtually formed at each of the positions where the first grid lines GL1 and the second grid lines GL2 intersect.

In the present embodiment, each of the light-emitting elements in the first display region A1 is formed so that the electrode center of each pixel electrode coincides with the intersection point P of the virtual regular grid pattern. In other words, in the plan view of the display device 1, the electrode center of each of the electrode 11E, the electrode 12E, and the electrode 13E is formed at a position overlapping any of a plurality of the intersection points P. Therefore, each of the light-emitting element 11, the light-emitting element 12, and the light-emitting element 13 is arranged along the first direction D1 and the second direction D2.

For example, a distance between two points being two of the plurality of intersection points P adjacent to each other is defined as a length LP. In such a case, each electrode 11E is formed so that the electrode centers of the electrodes 11E adjacent to each other are spaced from each other by twice the length LP in each of the first direction D1 and the second direction D2. Each electrode 12E is formed so that the electrode centers of the electrodes 12E adjacent to each other are spaced from each other by twice the length LP in either the first direction D1 or the second direction D2. Each electrode 13E is formed so that the electrode centers of the electrodes 13E adjacent to each other are spaced from each other by twice the length LP in each of the first direction D1 or the second direction D2, similarly to each electrode 11E. Note that each electrode 12E is formed so that a length between the electrode centers of the electrode 11E and the electrode 13E adjacent to each other is separated by the length LP in each of the first direction D1 or the second direction D2.

Therefore, in the first display region A1, the distance between the electrode 11E and the electrode 12E adjacent to each other is the same. In the same way, in the first display region A1, the distance between the electrode 12E and the electrode 13E adjacent to each other is the same, and the distance between the electrode 11E and the electrode 13E adjacent to each other is the same.

The electrode 11E and the electrode 13E may have, for example, a square shape in the plan view of the display device 1. In such a case, the electrode center of each of the electrode 11E and the electrode 13E may be an intersection point of two diagonal lines. The electrode 12E may have, for example, a rounded rectangular shape in which a pair of straight lines facing each other are connected by a curved line in the plan view of the display device 1. In the plan view of the display device 1, one of two electrodes 12E adjacent to each other may have a longitudinal direction orthogonal to the other. In such a case, the electrode center of the electrode 12E may be an intersection point of bisectors of the electrode 12E in each of the longitudinal direction and the lateral direction of the electrode 12E.

For example, in the plan view of the display device 1, each of the light-emitting region 11L, the light-emitting region 12L, and the light-emitting region 13L may have a shape geometrically similar to that of the electrode 11E, the electrode 12E, and the electrode 13E, respectively. In such a case, in the plan view of the display device 1, the center of each of the light-emitting region 11L, the light-emitting region 12L, and the light-emitting region 13L may coincide with the electrode center of the electrode 11E, the electrode 12E, and the electrode 13E, respectively.

In the plan view of the display device 1, an electrode area of each electrode 13E may be smaller than that of each electrode 11E, and an electrode area of each electrode 12E may be smaller than that of each electrode 13E. As a result, in the plan view of the display device 1, the area of each light-emitting region 13L may be smaller than that of each light-emitting region 11L, and the area of each light-emitting region 12L may be smaller than that of each light-emitting region 13L.

For example, in the present embodiment, the light-emitting element 11 may emit light with a first color, the light-emitting element 12 may emit light with a second color, and the light-emitting element 13 may emit light with a third color. Herein, in the present specification, the first color may be blue, the second color may be green, and the third color may be red. In other words, the light-emitting element 11 may be a blue light-emitting element emitting blue light, the light-emitting element 12 may be a green light-emitting element emitting green light, and the light-emitting element 13 may be a red light-emitting element emitting red light.

Note that in the present embodiment, the blue light refers to, for example, light having a light-emitting central wavelength in a wavelength band of equal to or greater than 380 nm and equal to or less than 500 nm. The green light refers to, for example, light having a light-emitting central wavelength in a wavelength band of greater than 500 nm and 600 nm or less. The red light refers to light having a light-emitting central wavelength in a wavelength band of greater than 600 nm and 780 nm or less.

The first display region A1 includes, for example, a pixel circuit including a plurality of the pixel circuits that drives a pixel electrode for each light-emitting element. Each pixel circuit may drive each pixel electrode, based on a signal transmitted from the driver of the frame portion NA, and control light emission from each light-emitting portion. Each pixel circuit may include a thin film transistor formed by a method described below.

For example, a plurality of first signal lines extending substantially in the up and down direction of the display device 1 and a plurality of second signal lines extending substantially in the right and left direction of the display device 1 may be formed in the display portion DA. A signal from the driver of the frame portion NA may be applied to each of the first signal lines and the second signal lines. In the first display region A1, each of the first signal line and the second signal line may overlap each of the first grid lines GL1 and each of the second grid lines GL2, in the plan view of the display device 1. In other words, in the first display region A1, the intersection point of each of the first grid lines GL1 and each of the second grid lines GL2 may coincide with each of the intersection points P in the plan view of the display device 1. In such a case, in the display device 1, each pixel circuit that drives each light-emitting element in the first display region A1 can be arranged in the vicinity of each light-emitting element, and a need for forming a lead wiring line and the like is reduced. Each pixel circuit may drive each light-emitting element in accordance with a signal from the corresponding first signal line and second signal line.

In the present embodiment, a set including at least one of the light-emitting elements 11, at least one of the light-emitting elements 12, and at least one of the light-emitting elements 13 may be regarded as a pixel in the first display region A1. For example, the first display region A1 may include a plurality of pixels each including one of the light-emitting elements 11, two of the light-emitting elements 12, and one of the light-emitting elements 13. In such a case, the pixel electrodes of the two light-emitting elements 12 included in the same pixel may be short-circuited to each other, and may be driven by the same pixel circuit. In other words, each of the four light-emitting elements included in the pixel may be driven by three pixel circuits.

### Second Display Region

The second display region A2 includes, for example, a plurality of light-emitting elements 21 serving as second light-emitting elements, a plurality of light-emitting elements 22 serving as fourth light-emitting elements, and a plurality of light-emitting elements 23 serving as fifth light-emitting elements. Each of the plurality of light-emitting elements 21, the plurality of light-emitting elements 22, and the plurality of light-emitting elements 23 may have the same configurations as the light-emitting element 11, the light-emitting element 12, and the light-emitting element 13, except for differences in formation position and in shape.

For example, the light-emitting element 21, the light-emitting element 22, and the light-emitting element 23 include the electrode 21E, an electrode 22E, and an electrode 23E serving as an electrode, respectively, and the electrode 21E, the electrode 22E, and the electrode 23E include a plurality of the electrodes 21E, a plurality of the electrodes 22E, and a plurality of the electrodes 23E. Each of the electrode 21E, the electrode 22E, and the electrode 23E is a pixel electrode formed for each subpixel of the display portion DA. As described below, the display device 1 includes a function layer of each light-emitting element formed at a position overlapping each of the electrode 21E, the electrode 22E, and the electrode 23E, and a common electrode common to each pixel electrode in the plan view of the display device 1. Therefore, as illustrated in FIG. 1, in the second display region A2, a light-emitting region 21L, a light-emitting region 22L, and a light-emitting region 23L are formed at a position overlapping each of the electrode 21E, the electrode 22E, and the electrode 23E, in the plan view of the display device 1, and the light-emitting region 21L, the light-emitting region 22L, and the light-emitting region 23L include a plurality of the light-emitting regions 21L, light-emitting regions 22L, and light-emitting regions 23L.

In the present embodiment, each light-emitting element in the second display region A2 is formed such that the electrode center of the pixel electrode thereof is displaced from the intersection point P. In other words, in the plan view of the display device 1, the electrode center of each of the electrode 21E, the electrode 22E, and the electrode 23E in the second display region A2 is formed at a position displaced from the intersection point P.

For example, in the present embodiment, the light-emitting element 21 may emit light with a first color, the light-emitting element 22 may emit light with a second color, and the light-emitting element 23 may emit light with a third color. In other words, the light-emitting element 21 may be a blue light-emitting element emitting blue light, the light-emitting element 22 may be a green light-emitting element emitting green light, and the light-emitting element 23 may be a red light-emitting element emitting red light.

In the present embodiment, a set including at least one of the light-emitting elements 21, at least one of the light-emitting elements 22, and at least one of the light-emitting elements 23 in the second display region A2 may be regarded as a pixel in the second display region A2. For example, the second display region A2 may include a plurality of pixels each including one of the light-emitting elements 21, two of the light-emitting elements 22, and one of the light-emitting elements 23. In other words, the number of the light-emitting elements 22 may be greater than the number of the light-emitting elements 21. In such a case, the electrodes 22E of the two light-emitting elements 22 included in the same pixel may be short-circuited to each other, and may be driven by the same pixel circuit. In other words, each of the four light-emitting elements included in the pixel may be driven by three pixel circuits.

In the plan view of the display device 1, the electrode area of each electrode 23E may be smaller than the electrode area of each electrode 21E, and the electrode area of each electrode 22E may be smaller than the electrode area of each electrode 23E. Accordingly, in the plan view of the display device 1, the area of each light-emitting region 23L may be smaller than the area of each light-emitting region 21L, and the area of each light-emitting region 22L may be smaller than the area of each light-emitting region 23L.

In general, a human eye has a characteristic that the sensitivity of luminance is higher for green light than for blue light and red light, and the sensitivity of luminance is higher for red light than for blue light. Therefore, when the light-emitting element 21 emits blue light, the light-emitting element 22 emits green light, and the light-emitting element 23 emits red light, the display device 1 can improve the apparent resolution if the number of the light-emitting elements 22 is greater than the number of light-emitting elements of the other luminescent colors. If the area is decreased in the order of the light-emitting region 21L, the light-emitting region 23L, and the light-emitting region 22L, the display device 1 makes it easy to improve the apparent white balance. If the area of each light-emitting region is decreased and the area of the pixel electrode is decreased, it is possible to increase the ratio of the area of a light-transmitting region A4 in the second display region A2.

### Third Display Region

The third display region A3 includes, for example, the plurality of light-emitting elements 21, the plurality of light-emitting elements 22, and the plurality of light-emitting elements 23 described above. Each of the light-emitting elements 21, the light-emitting elements 22, and the light-emitting elements 23 in the third display region A3 may have the same configuration as each of the light-emitting elements 21, the light-emitting elements 22, and the light-emitting elements 23 in the second display region A2, respectively, except for the positional relationship therebetween.

Each light-emitting element in the third display region A3 is formed such that the electrode center of each pixel electrode coincides with the intersection point P. In other words, in the plan view of the display device 1, the electrode center of each of the electrode 21E, the electrode 22E, and the electrode 23E in the third display region A3 is formed at a position overlapping any of the plurality of intersection points P. Therefore, each of the light-emitting element 21, the light-emitting element 22, and the light-emitting element 23 in the third display region A3 is arranged along the first direction D1 and the second direction D2.

Therefore, in the third display region A3, the distance between the electrode 21E and the electrode 22E adjacent to each other is the same, the distance between the electrode 22E and the electrode 23E adjacent to each other are the same, and the distance between the electrode 21E and the electrode 23E adjacent to each other is the same.

The third display region A3 further includes a pixel circuit for driving each light-emitting element in the second display region A2. In other words, the pixel circuit that drives each light-emitting element in the second display region A2 is formed on the periphery of the second display region A2 in the plan view of the display device 1. For example, as illustrated in FIG. 1, the third display region A3 includes the pixel circuit 21D that drives the light-emitting element 21 in the second display region A2. For example, the pixel circuit 21D drives the light-emitting element 21 in the second display region A2 via the transparent wiring line 46 described below.

Note that the third display region A3 may include, in addition to the pixel circuit 21D illustrated in FIG. 1, a pixel circuit that drives each of the light-emitting elements 22 and 23 in the second display region A2. The third display region A3 may include a pixel circuit that drives each light-emitting element in the third display region A3.

### Layer Structure

A layer structure of the display device 1 in the second display region A2 and the third display region A3 will be described in detail with reference to FIG. 4. FIG. 4 is a schematic side sectional view illustrating a side section of a plane substantially perpendicular to the display surface of the display device 1 in an enlarged manner in or near the second display region A2 and the third display region A3.

The display device 1 includes a substrate 31 having optical transparency, such as a glass substrate or a film substrate. The display device 1 includes a first inorganic interlayer film 32, a second inorganic interlayer film 33, a third inorganic interlayer film 34, a first organic interlayer film 35, a second organic interlayer film 36, a third organic interlayer film 37, and a fourth organic interlayer film 38, all of which have optical transparency, in this order on the substrate 31. The substrate 31, each inorganic interlayer film, and each organic interlayer film described above may be formed in the display portion DA including the first display region A1, the second display region A2, and the third display region A3.

The first inorganic interlayer film 32, the second inorganic interlayer film 33, and the third inorganic interlayer film 34 are formed by, for example, forming an inorganic oxide film or the like by a CVD method or the like. The first organic interlayer film 35, the second organic interlayer film 36, the third organic interlayer film 37, and the fourth organic interlayer film 38 are formed by forming an organic coating film having optical transparency such as polyimide by a coating method, a photolithography method, or the like. The display device 1 further includes a common electrode 39 formed on the upper surface of the fourth organic interlayer film 38, the common electrode 39 being formed in common with the pixel electrode of the display portion DA.

In the present embodiment, each pixel electrode in the second display region A2 and the third display region A3, including the electrode 21E, is formed between the third organic interlayer film 37 and the fourth organic interlayer film 38. For example, in the second display region A2 and the third display region A3, a function layer 21F including a light-emitting layer is each formed between each electrode 21E and the common electrode 39. Accordingly, the light-emitting element 21 is each formed in the second display region A2 and the third display region A3 by each electrode 21E, each function layer 21F, and the common electrode 39.

Note that each pixel electrode in the first display region A1 may be formed between the third organic interlayer film 37 and the fourth organic interlayer film 38. For example, in the first display region A1, the function layer including a light-emitting layer may be each formed between each pixel electrode and the common electrode 39. Thus, the light-emitting element may be each formed in the first display region A1 by each pixel electrode, each function layer, and the common electrode 39.

When each pixel electrode in the display portion DA is an anode of a light-emitting element, each function layer in the display portion DA may include, for example, a hole transport layer, a light-emitting layer, and an electron transport layer in this order from the pixel electrode side. In such a case, the light-emitting layer may be, for example, an organic light-emitting layer containing an organic light-emitting material, in other words, the display portion DA of the display device 1 may include an OLED panel having a plurality of organic light-emitting elements. Alternatively, the light-emitting layer may be, for example, a quantum dot light-emitting layer containing semiconductor nanoparticles, in other words, quantum dots as a light-emitting material.

The display device 1 drives the light-emitting element 21 to cause the light-emitting layer of the function layer 21F to emit light LR with the first color. Thus, display is performed in the display portion DA including the second display region A2 and the third display region A3.

In the third display region A3, the display device 1 further includes a first conductive film 41, a semiconductor film 42, a second conductive film 43, a third conductive film 44, a fourth conductive film 45, and a transparent wiring line 46 in this order from a side of the substrate 31. The first conductive film 41 is located between the substrate 31 and the first inorganic interlayer film 32. The semiconductor film 42 is located between the first inorganic interlayer film 32 and the second inorganic interlayer film 33. The second conductive film 43 is located between the second inorganic interlayer film 33 and the third inorganic interlayer film 34. The third conductive film 44 is located between the third inorganic interlayer film 34 and the first organic interlayer film 35. The fourth conductive film 45 is located between the first organic interlayer film 35 and the second organic interlayer film 36. The transparent wiring line 46 is located between the second organic interlayer film 36 and the third organic interlayer film 37.

Here, the transparent wiring line 46 is electrically connected to the fourth conductive film 45 via a contact hole 46C formed in the second organic interlayer film 36. The transparent wiring line 46 is also routed to the second display region A2, and is electrically connected to the electrode 21E via a contact hole 21C formed in the third organic interlayer film 37.

The first conductive film 41, the second conductive film 43, the third conductive film 44, and the fourth conductive film 45 all have electrical conductivity, and may be, for example, a conductive film having light reflectivity including a metal film. The transparent wiring line 46 is a transparent member having a light-transmitting property and an electrical conductivity. Each pixel circuit in the third display region A3 may be formed by forming a thin film transistor with the first conductive film 41, the semiconductor film 42, the second conductive film 43, the third conductive film 44, and the fourth conductive film 45.

Note that the pixel circuit that drives each light-emitting element in the third display region A3 may be formed by forming a thin film transistor in the third display region A3, as in the pixel circuit that drives each light-emitting element in the second display region A2. The pixel circuit that drives each light-emitting element in the first display region A1 may be formed by forming a thin film transistor in the first display region A1. Therefore, the first conductive film 41, the semiconductor film 42, the second conductive film 43, the third conductive film 44, and the fourth conductive film 45 may also be formed in the first display region A1.

### Position where Light-Emitting Region is Formed

As illustrated in FIG. 4, in the present embodiment, the function layer of each light-emitting element in the display portion DA including the first display region A1, the second display region A2, and the third display region A3 is formed in an opening formed in the fourth organic interlayer film 38. For example, the function layer may be formed by forming the substrate 31 to the fourth organic interlayer film 38, then forming an opening in the fourth organic interlayer film 38 at a position overlapping each pixel electrode in the plan view of the display device 1, and forming a layer containing a material of the function layer in the opening.

In such a case, the position of the opening of the fourth organic interlayer film 38 in the second display region A2 may be displaced in accordance with the displacement of the pixel electrode corresponding to the opening. In other words, in the plan view of the display device 1, the center of the opening of the fourth organic interlayer film 38 in the second display region A2 may be displaced from the intersection point P. Accordingly, the center of the light-emitting region of each light-emitting element in the second display region A2 and the intersection point P can be displaced from each other in accordance with the displacement between the electrode center of the pixel electrode of each light-emitting element in the second display region A2 and the intersection point P.

For example, the formation pattern of the material of the function layer in the second display region A2 may be identical to the formation pattern of the material of the function layer in the first display region A1 and the third display region A3. In such a case, it is sufficient that the position of each opening of the fourth organic interlayer film 38 in the second display region A2 is displaced so that the position of the opening of the fourth organic interlayer film 38 in the second display region A2 is included in the position where each function layer is formed in the second display region A2 in the plan view of the display device 1.

For example, in the plan view of the display device 1, the pixel electrode of each light-emitting element in the second display region A2 may overlap the intersection point P. The magnitude of the displacement between the electrode center of the pixel electrode of each light-emitting element in the second display region A2 and each intersection point P may be equal to or less than ½ the diameter of the light-emitting region of each light-emitting element in the second display region A2. Accordingly, the above-described method can also reduce the possibility that the function layer is not formed in a part of the opening of the fourth organic interlayer film 38 in the second display region A2.

For example, it is assumed that the function layer is formed by vapor deposition using a vapor deposition mask such as a metal mask having a plurality of openings. In such a case, the vapor deposition mask may have the same shape and arrangement pattern of the opening at the position corresponding to the first display region A1 and the third display region A3 and the position corresponding to the second display region A2. In such a case, if the position of each opening of the fourth organic interlayer film 38 in the second display region A2 is controlled in the plan view of the display device 1, the position where each light-emitting region in the second display region A2 is formed can be controlled.

For example, it is assumed that the function layer is formed by an inkjet method in which a material of the function layer is dropped in the opening of the fourth organic interlayer film 38. In such a case, a position where the material of the function layer is dropped may be a position corresponding to each intersection point P in any of the first display region A1, the second display region A2, and the third display region A3. In such a case, as long as each opening of the fourth organic interlayer film 38 in the second display region A2 and the intersection point P overlap each other in the plan view of the display device 1, it is possible to reduce the possibility that the function layer is not formed in a part of the opening of the fourth organic interlayer film 38 in the second display region A2.

### Capturing Imaging Light Into Camera

In the second display region A2, the display device 1 further includes a camera unit CU serving as a camera including an image element and the like on the side of the substrate 31 opposite to the light-emitting element 21. Imaging light LT incident from the display surface side of the display device 1 is incident on the camera unit CU. In particular, in the second display region A2, a member having optical transparency including the transparent wiring line 46 is formed except for each pixel electrode. Therefore, the light-transmitting region A4 through which the imaging light LT is transmitted from the common electrode 39 to the camera unit CU is formed between the pixel electrodes in the second display region A2.

Therefore, the imaging light LT incident on the light-transmitting region A4 from the display surface side of the display device 1 is fetched into the camera unit CU. Thus, the display device 1 can capture an image on the display surface side with respect to the substrate 31 by the camera unit CU. Therefore, the display device 1 can capture an image on the display surface side of the OLED panel by the camera unit CU while performing display on the OLED panel, for example. Note that the display device 1 may also capture an image from the back surface side of the display device 1, that is, the side opposite to the display surface with respect to the substrate 31, by the camera unit CU.

As described above, the imaging light LT from the display surface side of the display device 1 is fetched into the camera unit CU in the light-transmitting region A2 located between the pixel electrodes in the second display region A4. Therefore, the imaging light LT fetched into the camera unit CU passes through a gap between the pixel electrodes in the second display region A2.

### Interference of Diffraction Light of Imaging Light

Here, the influence of each pixel electrode in the second display region A2 on the imaging light LT fetched into the camera unit CU will be considered.

For example, it is assumed that in the plan view of the display device 1, the electrode center of each pixel electrode in the second display region A2 coincides with a certain intersection point P, as in the electrode center of each pixel electrode in the first display region A1 and the third display region A3. In such a case, each of all the pixel electrodes in the second display region A2 has substantially the same positional relationship with the other adjacent to each other. Therefore, in any direction of display surface directions of the display device 1, a portion formed with a pixel electrode and a portion not formed with a pixel electrode wiring line in the second display region A2 are periodically present.

The imaging light LT incident on the light-transmitting region A4 is diffracted when passing through each of spaces between the pixel electrodes, and a plurality of diffraction light beams may interfere with each other. Here, when the electrode center of each pixel electrode in the second display region A2 is on the intersection point P, each pixel electrode in the light-transmitting region A4 are periodically arranged, and thus, each pixel electrode may behave like diffraction lattices and increase the interference of the diffraction light described above.

When the plurality of imaging light beams LT fetched into the camera unit CU interfere with each other, light with a specific wavelength is enhanced or attenuated, and the quality of imaging by the camera unit CU may be deteriorated.

In the present embodiment, each light-emitting element in the second display region A2 is formed such that the electrode center of the pixel electrode thereof is displaced from the intersection point P. Therefore, the periodicity of the presence or absence of the pixel electrode in the light-transmitting region A4 in any direction on the display surface is small. Therefore, the display device 1 according to the present embodiment can reduce interference between diffraction light beams of the imaging light LT passing through spaces between the pixel electrodes. Therefore, the display device 1 reduces interference between diffraction light beams of the imaging light LT fetched into the camera unit CU from the second display region A2, particularly, the light-transmitting region A4, and reduces deterioration in quality of imaging by the camera unit CU.

### Supplement

In the present embodiment, for example, each light-emitting element in the second display region A2 may be formed such that any electrode centers of the pixel electrodes are displaced from the intersection point P. With the above configuration, the display device 1 can more efficiently reduce the periodicity of the presence or absence of the pixel electrode of each light-emitting element in the second display region A2.

In the present embodiment, the direction and the distance of the displacement of the electrode center of each light-emitting element from the intersection point P in the second display region A2 may be random. For example, in the present embodiment, the direction and distance of the displacement of each pixel electrode in the second display region A2 from the intersection point P may be determined according to a random number table generated separately.

With the above configuration, the periodicity of the arrangement position of each pixel electrode in the second display region A2 is further reduced as compared with a case where the displacement is determined according to a predetermined rule. Therefore, with the above configuration, the display device 1 can further reduce interference between diffraction light beams of the imaging light LT fetched into the camera unit CU from the light-transmitting region A4.

In the present embodiment, the electrode 21E, the electrode 22E, and the electrode 23E may be each formed at a position overlapping the intersection point P in the plan view of the display device 1. With the above configuration, the display device 1 reduces the possibility that the displacement between the center of the light-emitting region of each light-emitting element and the intersection point P in the second display region A2 is too large, and reduces the possibility that the display quality in the second display region A2 is deteriorated.

For example, in the present embodiment, a random number table of XY coordinates in which variance is given with equal probability in a range of ½ the diameter of the light-emitting region may be set to each light-emitting element in the second display region A2. In the present embodiment, the direction and the distance of the displacement of the electrode center of each light-emitting element in the second display region A2 from the intersection point P may be determined according to the random number table.

In such a case, the magnitude of the displacement of the electrode center of each light-emitting element from the intersection point P in the second display region A2 is equal to or less than ½ of the diameter of each light-emitting region. With the above configuration, the display device 1 reduces the possibility that the displacement between the center of the light-emitting region of each light-emitting element and the intersection point P in the second display region A2 is too large, and reduces the possibility that the display quality in the second display region A2 is deteriorated.

The random number table may be represented by a polar form of an argument θ and a deviation r. The random number table may be set to the entire area of the second display region A2. Alternatively, the second display region A2 may be divided into a plurality of small regions, and an individual random number table may be set to each small region, or the same random number table may be set to each small region.

Therefore, in the second display region A2, the distance between the electrode 21E and the electrode 22E adjacent to each other may be different. In the same way, in the second display region A2, the distance between the electrode 22E and the electrode 23E adjacent to each other may be different, and the distance between the electrode 21E and the electrode 23E adjacent to each other may be different.

However, the electrode centers of some of the pixel electrodes in the second display region A2 may be formed so as to coincide with the intersection point P in the plan view of the display device 1. For example, while the second display region A2 includes the light-emitting element 21 in which the electrode center of the electrode 21E is displaced from the intersection point P, the second display region A2 may include the light-emitting element 21 in which the electrode center of the electrode 21E coincides with the intersection point P as a third light-emitting element.

In the above configuration, the electrode centers of some of the electrodes 21E of the light-emitting elements 21 in the second display region A2 are displaced from the intersection point P, and thus, the display device 1 can reduce the periodicity of the presence or absence of the pixel electrode in the second display region A2. On the other hand, with the above configuration, the electrode centers of some of the electrodes 21E of the light-emitting elements 21 in the second display region A2 overlap the intersection point P. Therefore, the display device 1 reduces a difference between the arrangement pattern of some of the light-emitting elements 11 in the first display region A1 and the arrangement pattern of the light-emitting elements 22 in the second display region A2. Therefore, the display device 1 according to the present embodiment reduces a difference in display pattern between the first display region A1 and the second display region A2, and improves the display quality.

In the present embodiment, the plurality of intersection points P are located along the first direction D1 and the second direction D2. The electrode center of the pixel electrode of each light-emitting element in the second display region A2 is displaced from the intersection point P in at least one of the first direction D1 and the second direction D2. This allows the display device 1 to reliably cause the displacement of the electrode center of the pixel electrode of each light-emitting element in the second display region A2 with respect to the intersection point P with a simple configuration. In particular, the above-described displacement of the electrode center of each light-emitting element in the second display region A2 is easily realized by setting the displacement according to the random number table of the XY coordinates as described above. Therefore, with the above configuration, the displacement of the electrode center of each light-emitting element in the second display region A2 can be realized with a simple design.

In the present embodiment, each of the electrode 21E, the electrode 22E, and the electrode 23E may have a circular shape in the plan view of the display device 1. In such a case, the electrode center of each of the electrode 21E, the electrode 22E, and the electrode 23E may be the center of the circle. In other words, each of the electrode 21E, the electrode 22E, and the electrode 23E may have a different shape from the electrode 11E, the electrode 12E, and the electrode 13E, respectively. In other words, the shape of the electrode of each light-emitting element may be different from each other between the first display region A1 and the second display region A2. With the above configuration, the display device 1 can further reduce the interference of the imaging light in the light-transmitting region A4 in the boundary with the first display region A1 and the vicinity thereof and between the pixel electrode of the light-emitting element in the first display region A1 and the pixel electrode of the light-emitting element in the second display region A2.

The electrode area of each of the electrode 21E, the electrode 22E, and the electrode 23E may be smaller than the electrode area of each of the electrode 11E, the electrode 12E, and the electrode 13E. In other words, in the plan view of the display device 1, the size of the pixel electrode of each light-emitting element in the second display region A2 may be smaller than the size of the pixel electrode of each light-emitting element in the first display region A1. With the above configuration, the display device 1 can reduce the ratio of the area occupied by the pixel electrode of each light-emitting element in the second display region A2 in the plan view relative to that in the first display region A1. Therefore, in the display device 1, the area of the light-transmitting region A4 in the second display region A2 is more easily secured.

Note that in the plan view of the display device 1, the size of the pixel electrode of each light-emitting element in the third display region A3 may be also smaller than the size of the pixel electrode of each light-emitting element in the first display region A1. Accordingly, in the third display region A3, the ratio of the region occupied by each pixel electrode is reduced. Therefore, in the display device 1, it is easier to form, in the third display region A3, the pixel circuit that drives each light-emitting element in both the second display region A2 and the third display region A3.

For example, in the plan view of the display device 1, the light-emitting region 21L, the light-emitting region 22L, and the light-emitting region 23L may each have shapes geometrically similar to those of the electrode 21E, the electrode 22E, and the electrode 23E, respectively. Additionally, in the plan view of the display device 1, the center of each of the light-emitting region 21L, the light-emitting region 22L, and the light-emitting region 23L may coincide with that of the electrode 21E, the electrode 22E, and the electrode 23E, respectively. With such a configuration, the display device 1 can efficiently increase the ratio of the area of the light-emitting region to the area of the pixel electrode in each light-emitting element in the second display region A2.

In the present embodiment, in at least one of sets of the light-emitting element 21 and the light-emitting element 22 adjacent to each other, the displacement directions of the electrode centers thereof from the intersection point P may be different from each other. In other words, in the electrode 21E and the electrode 22E adjacent to each other, the direction in which the electrode center of the electrode 21E is displaced from the intersection point P may be different from the direction in which the electrode center of the electrode 22E is displaced from the intersection point P. With the above configuration, the display device 1 can further reduce interference of imaging light between the light-emitting element 21 and the light-emitting element 22.

In at least one of sets of the light-emitting element 21 and the light-emitting element 23 adjacent to each other, the displacement directions of the electrode centers thereof from the intersection point P may be different from each other. In other words, in the electrode 21E and the electrode 23E adjacent to each other, the direction in which the electrode center of the electrode 21E is displaced from the intersection point P may be different from the direction in which the electrode center of the electrode 23E is displaced from the intersection point P. With the above configuration, the display device 1 can further reduce interference of imaging light between the light-emitting element 21 and the light-emitting element 23.

The pixel electrode of each light-emitting element in the display portion DA is a light-reflecting electrode. Therefore, the display device 1 can more efficiently increase the intensity of light emitted from each light-emitting element. When the pixel electrode of each light-emitting element in the display portion DA is an anode, the display device 1 improves the degree of freedom of the material of the pixel electrode to use the pixel electrode as a light-reflecting electrode. On the other hand, the light-transmitting region A4 is formed in the second display region A2, and thus, the display device 1 can realize capture of the imaging light into the camera unit CU while securing the intensity of the light emitted from each light-emitting element.

In the present embodiment, the transparent wiring line 46 that electrically connects the pixel electrode of any of the light-emitting elements in the second display region A2 and any of the pixel circuits in the third display region A3 is formed in the second display region A2. Therefore, in the display device 1, the pixel circuit for driving the light-emitting element having the pixel electrode connected to the transparent wiring line 46 can be formed at a position away from the light-emitting element. The transparent wiring line 46 has a light-transmitting property, and thus, the display device 1 can reduce inhibition of the transparent wiring line 46 from capturing the imaging light into the camera unit CU even when the transparent wiring line 46 is formed in the light-transmitting region A4.

In particular, the pixel circuit that drives each light-emitting element in the second display region A2 is located in the third display region A3 located on the periphery of the second display region A2, and drives each light-emitting element in the second display region A2 via the transparent wiring lines 46. Therefore, the display device 1 can reduce inhibition from capturing the imaging light into the camera unit CU by the pixel circuit that drives each light-emitting element in the second display region A2.

### Second Embodiment

### Gradual Reduction of Pixel Electrode

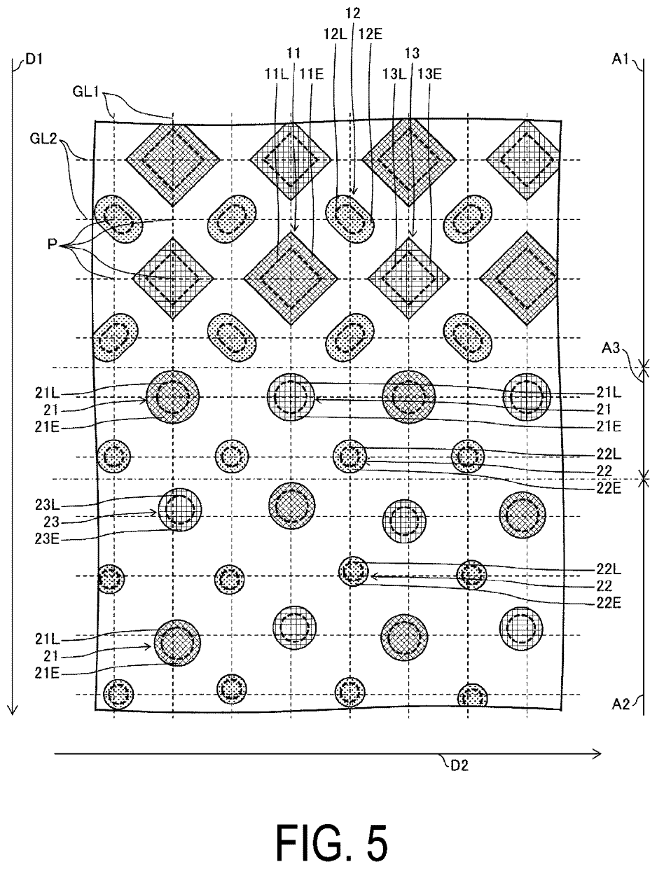

FIG. 5 is a further enlarged view of the boundary between the first display region A1 and the third display region A3 and the vicinity thereof and the boundary between the second display region A2 and the third display region A3 and the vicinity thereof in the display device 1 according to the present embodiment. In particular, FIG. 5 is a view illustrating a position corresponding to the schematic enlarged view illustrated in FIG. 1.

The display device 1 according to the present embodiment is different from the display device 1 according to the previous embodiment in size of the pixel electrode and the light-emitting region of each light-emitting element in the second display region A2 and the third display region A3.

In the second display region A2 and the third display region A3 in the present embodiment, the size of the electrode 21E of the light-emitting element 21 is different depending on the distance from the center of the second display region A2. In particular, in the present embodiment, the size of the electrode 21E in the second display region A2 and the third display region A3 decreases as the electrode 21E approaches the center of the second display region A2. On the other hand, the sizes of the light-emitting regions 21L in the second display region A2 and the third display region A3 may be constant regardless of the distances from the center of the second display region A2.

In the same way, in the second display region A2 and the third display region A3 in the present embodiment, the size of the electrode 22E of the light-emitting element 22 and the size of the electrode 22E of the light-emitting element 22 may be different depending on the distances from the center of the second display region A2. In particular, in the present embodiment, the size of each of the electrode 22E and the electrode 23E in the second display region A2 and the third display region A3 may decrease as the electrode 22E and the electrode 23E approach the center of the second display region A2. On the other hand, the size of each of the light-emitting region 22L and the light-emitting region 23L in the second display region A2 and the third display region A3 may be constant regardless of the distance from the center of the second display region A2.

Except for the above configuration, the display device 1 according to the present embodiment has the same configuration as the display device 1 according to the previous embodiment. For example, in the present embodiment, the electrode center of the pixel electrode of each light-emitting element is displaced from the intersection point P in the second display region A2. Therefore, in the present embodiment, the display device 1 also reduces interference between diffraction light beams of the imaging light LT fetched into the camera unit CU from the second display region A2, particularly, the light-transmitting region A4, and reduces degradation in quality of imaging by the camera unit CU.

In the present embodiment, the size of the electrode 21E of the light-emitting element 21 varies depending on the distance from the center of the second display region A2, and thus, the display device 1 can further reduce the periodicity of the presence or absence of the pixel electrode in the second display region A2.

Note that in the present embodiment, the size of the light-emitting region of each light-emitting element in the second display region A2 and the third display region A3 may be the same depending on the distance from the center of the second display region A2. On the other hand, the size of the light-emitting region of each light-emitting element in the second display region A2 and the third display region A3 may be different depending on the distance from the center of the second display region A2. For example, in the second display region A2 and the third display region A3, as the pixel electrode of each light-emitting element is smaller, the size of the light-emitting region of each light-emitting element may be smaller.

Here, when there is a difference in area of the light-emitting region of the plurality of light-emitting elements in the display device 1, a difference also occurs in drive current value of the light-emitting element necessary for obtaining the same luminance in the plurality of light-emitting elements. In particular, as the light-emitting region of the light-emitting element in the display device 1 is smaller, the drive current value of the light-emitting element required to obtain the same luminance in the light-emitting element tends to be greater. In general, the luminance deterioration of the light-emitting element tends to progress faster as the drive current value is greater. Therefore, when there is a difference in area of the light-emitting region of the plurality of light-emitting elements depending on the position of the display portion DA of the display device 1, a difference in luminance deterioration of the plurality of light-emitting elements is likely to occur.

For example, in the present embodiment, while the size of the electrode 21E gradually changes depending on the distance from the center of the second display region A2, the size of the light-emitting region 21L is the same regardless of the distance from the center of the second display region A2. In such a case, the display device 1 according to the present embodiment can reduce a rapid change in luminance deterioration of each light-emitting element due to a change in the position of the display portion DA, and improves the display quality. In particular, the display device 1 according to the present embodiment reduces a rapid change in luminance deterioration of each light-emitting element at the boundary of each of the first display region A1, the second display region A2, and the third display region A3, and reduces the visibility of the boundary.

### Third Embodiment

### Periodic Arrangement of Pixel Electrode of Green Light-Emitting Element

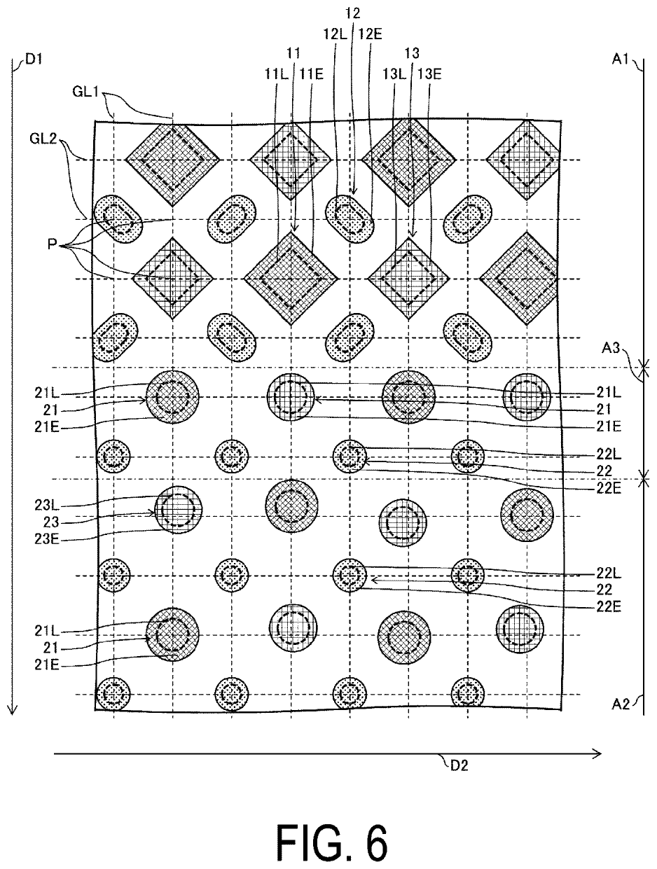

FIG. 6 is a further enlarged view of the boundary between the first display region A1 and the third display region A3 and the vicinity thereof and the boundary between the second display region A2 and the third display region A3 and the vicinity thereof in the display device 1 according to the present embodiment. In particular, FIG. 6 is a view illustrating a position corresponding to the schematic enlarged view illustrated in FIG. 1.

The display device 1 according to the present embodiment is different in configuration from the display device 1 according to the first embodiment described above in that the electrode center of each of the light-emitting elements 22 in the second display region A2 coincides with the intersection point P. In other words, the center of the electrode 22E according to the present embodiment coincides with the intersection point P. The center of the light-emitting region 22L according to the present embodiment may coincide with the intersection point P.

Therefore, the display device 1 according to the present embodiment reduces the difference between the arrangement pattern of the light-emitting element 12 in the first display region A1 and the arrangement pattern of the light-emitting element 22 in the second display region A2. Therefore, the display device 1 according to the present embodiment reduces a difference in display pattern between the first display region A1 and the second display region A2, and improves the display quality. In particular, when the light-emitting element 12 and the light-emitting element 22 emit green light that is relatively more easily visually recognized than blue light and red light, the display device 1 according to the present embodiment more efficiently exhibits the above effect.

On the other hand, except for the above configuration, the display device 1 according to the present embodiment has the same configuration as the display device 1 according to the described first embodiment. For example, in the present embodiment, the electrode center of the pixel electrode of each of the light-emitting elements 21 and 23 is displaced from the intersection point P in the second display region A2. Therefore, the display device 1 according to the present embodiment reduces interference between diffraction light beams of the imaging light LT fetched into the camera unit CU from the second display region A2, particularly, the light-transmitting region A4, and reduces degradation in quality of imaging by the camera unit CU while improving a display quality from the above reasons.

### Fourth Embodiment

### Periodic Arrangement of Pixel Electrode of Red Light-Emitting Element

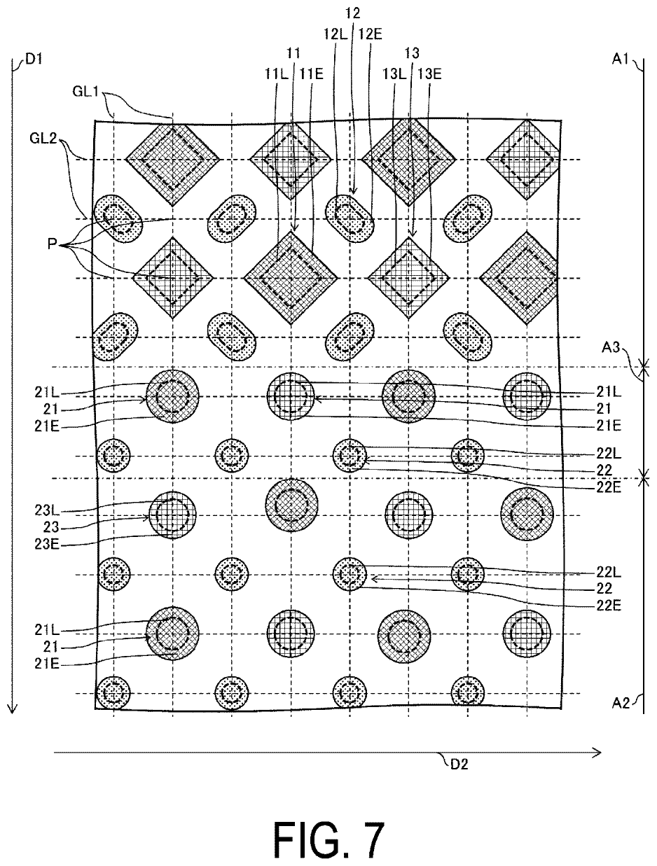

FIG. 7 is a further enlarged view of the boundary between the first display region A1 and the third display region A3 and the vicinity thereof and the boundary between the second display region A2 and the third display region A3 and the vicinity thereof in the display device 1 according to the present embodiment. In particular, FIG. 7 is a view illustrating a position corresponding to the schematic enlarged view illustrated in FIG. 1.

The display device 1 according to the present embodiment is different in configuration from the display device 1 according to the previous embodiment in that the electrode center of each of the light-emitting elements 23 in the second display region A2 coincides with the intersection point P. In other words, the center of the electrode 23E according to the present embodiment coincides with the intersection point P. The center of the light-emitting region 23L according to the present embodiment may coincide with the intersection point P.

Therefore, the display device 1 according to the present embodiment reduces a difference between the arrangement pattern of the light-emitting element 13 in the first display region A1 and the arrangement pattern of the light-emitting element 23 in the second display region A2. Therefore, the display device 1 according to the present embodiment further reduces a difference in display pattern between the first display region A1 and the second display region A2, and further improves the display quality. In particular, when the light-emitting element 13 and the light-emitting element 23 emit red light that is relatively more easily visually recognized than blue light, the display device 1 according to the present embodiment more efficiently exhibits the above effect.

On the other hand, except for the above configuration, the display device 1 according to the present embodiment has the same configuration as the display device 1 according to the described first embodiment. For example, in the present embodiment, the electrode center of the pixel electrode of each of the light-emitting elements 21 is displaced from the intersection point P in the second display region A2. Therefore, the display device 1 according to the present embodiment reduces interference between diffraction light beams of the imaging light LT fetched into the camera unit CU from the second display region A2, particularly, the light-transmitting region A4, and reduces degradation in quality of imaging by the camera unit CU while improving a display quality from the above reasons.

### Fifth Embodiment

### Periodic Arrangement of Light-Emitting Region

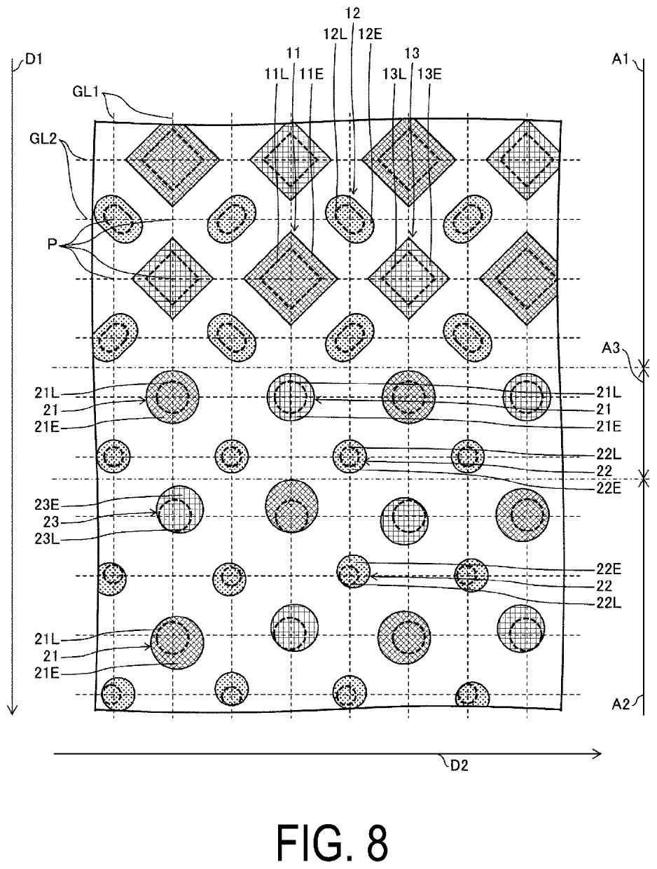

FIG. 8 is a further enlarged view of the boundary between the first display region A1 and the third display region A3 and the vicinity thereof and the boundary between the second display region A2 and the third display region A3 and the vicinity thereof in the display device 1 according to the present embodiment. In particular, FIG. 8 is a view illustrating a position corresponding to the schematic enlarged view illustrated in FIG. 1.

The display device 1 according to the present embodiment is different in configuration from the display device 1 according to the previous embodiment only in that the center of each light-emitting region in the second display region A2 coincides with the intersection point P. For example, while the electrode center of the electrode 21E of each light-emitting element 21 is displaced from the intersection point P, the center of the light-emitting region 21L of each light-emitting element 21 coincides with the intersection point P. The electrode centers of the electrode 22E of each light-emitting element 22 and of the electrode 23E of each light-emitting element 23 may be displaced from the intersection point P, and the centers of the light-emitting region 22L of each light-emitting element 22 and of the light-emitting region 23L of each light-emitting element 23 may coincide with the intersection point P.

With the above configuration, the display device 1 according to the present embodiment can reduce a difference in formation pattern of the light-emitting region of each light-emitting element in the first display region A1 and the second display region A2 while reducing the periodicity of the presence or absence of the pixel electrode in the second display region A2. Therefore, the display device 1 according to the present embodiment improves the display quality in the display portion DA while reducing the deterioration in quality of imaging by the camera unit CU.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

### REFERENCE SIGNS LIST

1 Display device
11 Light-emitting element (first light-emitting element)
21 Light-emitting element (second light-emitting element, third light-emitting element)
22 Light-emitting element (fourth light-emitting element)
23 Light-emitting element (fifth light-emitting element)
21D Pixel circuit
46 Transparent wiring line
A1 First display region (non-camera region)
A2 Second display region (camera region)
A3 Third display region (non-camera region)
D1 First direction
D2 Second direction
GL1 First grid line
GL2 Second grid line
CU Camera unit
DA Display portion
P Intersection point

1. A display device comprising:
a display portion including a camera region in which imaging light is introduced and a non-camera region,
wherein the non-camera region includes a plurality of first light-emitting elements each including an electrode and emitting a first color,
the camera region includes a plurality of second light-emitting elements each including an electrode and emitting the first color,
the plurality of first light-emitting elements are formed such that an electrode center of each of the plurality of first light-emitting elements coincides with an intersection point of a virtual regular grid pattern of the display portion, and
the plurality of second light-emitting elements are formed such that an electrode center of each of the plurality of second light-emitting elements is displaced from the intersection point.

2. The display device according to claim 1,
wherein the electrode center of each of the plurality of second light-emitting elements and the intersection point are randomly displaced from each other.

3. The display device according to claim 1,
wherein an electrode of each of the plurality of second light-emitting elements overlaps the intersection point.

4. The display device according to claim 2,
wherein a magnitude of the displacement is equal to or less than ½ of a diameter of a light-emitting region of each of the plurality of second light-emitting elements.

5. The display device according to claim 1,
wherein the regular grid pattern includes a plurality of grid lines arranged in a first direction and a second direction, and
an electrode center of each of the plurality of second light-emitting elements is displaced from the intersection point in at least one of the first direction and the second direction.

6. The display device according to claim 1,
wherein the electrode of each of the plurality of second light-emitting elements is different in shape from the electrode of each of the plurality of first light-emitting elements.

7. The display device according to claim 6,
wherein the plurality of second light-emitting elements have an electrode area smaller than an electrode area of the plurality of first light-emitting elements.

8. The display device according to claim 1,
wherein a plurality of the electrodes of the plurality of second light-emitting elements have electrode areas different from each other depending on a distance from a center of the camera region.

9. The display device according to claim 1,
wherein the camera region includes a third light-emitting element including an electrode and emitting the first color, and
the third light-emitting element is formed such that an electrode center coincides with the intersection point.

10. The display device according to claim 1,
wherein a center of a light-emitting region of each of the plurality of second light-emitting elements coincides with the intersection point.

11. The display device according to claim 1,
wherein the camera region includes a plurality of fourth light-emitting elements each including an electrode and emitting a second color, and
the plurality of fourth light-emitting elements have an electrode area smaller than an electrode area of the plurality of second light-emitting elements.

12. The display device according to claim 11,
wherein the plurality of fourth light-emitting elements are formed such that an electrode center of each of the plurality of fourth light-emitting elements is displaced from the intersection point.

13. The display device according to claim 12,
wherein in at least one set of one of the plurality of second light-emitting elements and one of the plurality of fourth light-emitting elements adjacent to each other, displacement directions of the electrode center of the one of the plurality of second light-emitting elements and the electrode center of the one of the plurality of fourth light-emitting elements from the intersection point are different from each other.

14. The display device according to claim 11,
wherein the plurality of fourth light-emitting elements are formed such that an electrode center of each of the plurality of fourth light-emitting elements coincides with the intersection point.

15. The display device according to claim 11,
wherein the number of the plurality of fourth light-emitting elements is greater than the number of the plurality of second light-emitting elements.

16. The display device according to claim 11,
wherein the first color is blue, and the second color is green.

17. The display device according to claim 1,
wherein the camera region includes a plurality of fifth light-emitting elements each including an electrode and emitting a third color, and
the plurality of fifth light-emitting elements have an electrode area smaller than that of the plurality of second light-emitting elements.

18. The display device according to claim 17,
wherein the plurality of fifth light-emitting elements are formed such that an electrode center of each of the plurality of fifth light-emitting elements is displaced from the intersection point.

19. The display device according to claim 18,
wherein in at least one set of one of the plurality of second light-emitting elements and one the plurality of fifth light-emitting elements adjacent to each other, displacement directions of the electrode center of the one of the plurality of second light-emitting elements and the electrode center of the one of the plurality of fifth light-emitting elements from the intersection point are different from each other.

20. The display device according to claim 17,
wherein the plurality of fifth light-emitting elements are formed such that an electrode center of each of the plurality of fifth light-emitting elements coincides with the intersection point.

21-26. (canceled)
